(19) United States
(12) Patent Application Publication
(10) Pub. No.: US 2013/0023097 A1
(43) Pub. Date: Jan. 24, 2013

(54) U-MOS TRENCH PROFILE OPTIMIZATION AND ETCH DAMAGE REMOVAL USING MICROWAVES

(71) Applicant: Robert J. Purtell, West Jordan, UT (US)

(72) Inventor: Robert J. Purtell, West Jordan, UT (US)

(21) Appl. No.: 13/549,182

(22) Filed: Jul. 13, 2012

Related U.S. Application Data
(60) Provisional application No. 61/507,728, filed on Jul. 14, 2011.

(51) Int. Cl. H01L 21/336; H01L 21/322

(52) U.S. Cl. 438/270; 438/473; 257/E21.429; 257/E21.318

(57) ABSTRACT

Semiconductor devices and methods for making such devices are described. The UMOS (U-shaped MOSFET) semiconductor devices can be formed by providing a semiconductor substrate, forming a trench in the substrate using a wet or dry etching process, and then radiating the trench structure using microwaves (MW) at low temperatures. The MW radiation process improves the profile of the trench and repairs the damage to the trench structure caused by the dry etching process. The microwave radiation can help re-align the Si or SiGe atoms in the semiconductor substrate and anneal out the defects present after the dry etching process. As well, the microwave radiation can getter atoms or ions used in the dry etching process that are left in the lattice of the trench structure. Other embodiments are described.

### CROSS-REFERENCE TO RELATED APPLICATION

This application claims priority of U.S. Provisional Application Ser. No. 61/507,728 filed Jul. 14, 2011, the entire disclosure of which is incorporated herein by reference.

### FIELD

This application relates generally to semiconductor devices and methods for making such devices. More specifically, this application describes UMOS semiconductor devices that contain trench structures with profiles that have been optimized by, and with etch damage that has been removed, using microwave radiation.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

One type of semiconductor device, a metal oxide silicon field effect transistor (MOSFET) device, can be widely used in numerous electronic apparatus, including automotive electronics, disk drives and power supplies. Some MOSFET devices can be formed in a trench that has been created in the substrate. One feature making the trench configuration attractive is that the current flows vertically through the channel of the MOSFET. This permits a higher cell and/or current channel densities than other MOSFETs where the current flows horizontally through the channel and then vertically through the drain. The trench MOSFET devices contain a gate structure formed in the trench where the gate structure contains a gate insulating layer on the sidewall and bottom of the trench (i.e., adjacent the substrate material) with a conductive layer that has been formed on the gate insulating layer.

### SUMMARY

This application describes semiconductor devices and methods for making such devices. The UMOS (U-shaped MOSFET) semiconductor devices can be formed by providing a semiconductor substrate, forming a trench in the substrate using a wet or dry etching process, and then radiating the trench structure using microwaves (MW) at low temperatures. The MW radiation process improves the profile of the trench and repairs the damage to the trench structure caused by the dry etching process. The microwave radiation can help re-align the Si or SiGe atoms in the semiconductor substrate and anneal out the defects present after the dry etching process. As well, the microwave radiation can getter atoms or ions used in the dry etching process that are left in the lattice of the trench structure.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer with a mask on the upper surface of the epitaxial layer;

FIG. 2 depicts some embodiments of methods for making a semiconductor structure containing a trench formed in the epitaxial layer; and

FIG. 3 depicts some embodiments of methods for making a semiconductor structure by radiating the trench with microwaves;

FIGS. 4-5 show some embodiments of methods for making a semiconductor structure by using a batch reactor;

FIG. 6 shows some embodiments of methods for making a semiconductor structure containing a conductive layer in the trench;

FIG. 7 shows some embodiments of methods for making a semiconductor structure containing a gate formed on a gate insulating layer;

FIG. 8 shows some embodiments of methods for making a semiconductor structure containing an insulation cap on the gate; and

FIG. 9 shows some embodiments of methods for making a semiconductor structure containing a trench MOSFET device.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the description refers to U-MOS (U-shaped MOSFET) semiconductor devices, it could be modified for any other types of semiconductor devices which may or may not contain gate structures formed in a trench, such as LDMOS or CMOS devices.

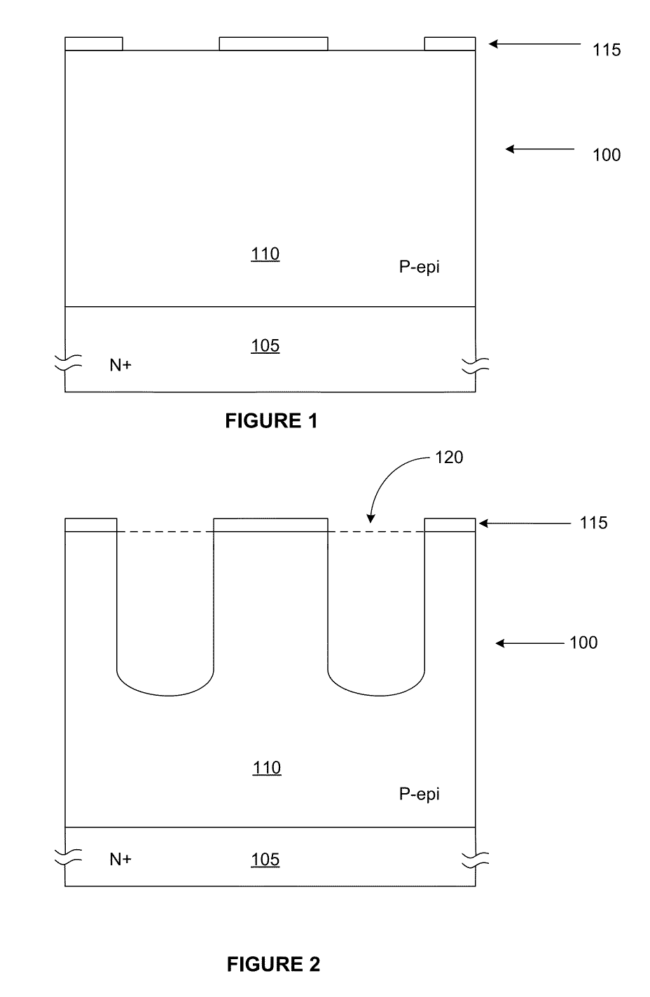

Some embodiments of the semiconductor devices and methods for making such devices are illustrated in the Figures and described herein. In these embodiments, the methods can begin as depicted in FIG. 1 when a semiconductor substrate 105 is first provided as part of the semiconductor structure 100. Any semiconductor substrate can be used as the substrate 105. Examples of some substrates include single-crystal silicon wafers, epitaxial Si layers, and/or bonded wafers such as used in silicon-on-insulator (SOI) technologies. Also, any other semiconducting material typically used for electronic devices can be used as the material for the substrate 105 under the right conditions, including Ge, SiGe, GaN, C, and/or any pure or compound semiconductors, such as III-V or II-VIs and their variants. Any or all of these substrates may remain undoped or be doped with any number of p-type or n-type dopant or combination of dopants. In some configurations, the substrate 105 comprises a single-crystal Si or SiGe wafer which is heavily doped with any type or number of n-type dopants to the desired concentration, as shown in FIG. 1.

The semiconductor structure 100 can optionally contain one or more epitaxial (or “epi”) layers located on a portion of the upper surface of the substrate 105. In FIG. 1, the individual epitaxial layer (or multiple epitaxial layers) are depicted as epitaxial layer 110. In some configurations, the epitaxial layer 110 covers substantially the entire upper surface of substrate 105. Where Si is used as the material for the substrate 105, the epitaxial layer 110 comprises Si. The epitaxial layer(s) 110 can be provided using any process, including any epitaxial deposition process. In some instances, the epitaxial layer(s) can be lightly doped with any type of number of p-type dopants, as shown in FIG. 1.

Next, as shown in FIG. 2, a trench 120 can be formed in the epitaxial layer 110 (and optionally in the substrate 105). The trench 120 can be formed by any process, including using a mask 115 formed on the upper surface of the epitaxial layer 110, as shown in FIG. 1. The trench 120 is then created by etching the material of the epitaxial layer 110 (and, if desired, the substrate 105) using any etchant. In some embodiments, the epitaxial layer 110 can be etched using a dry etching process until the trench 120 has reached the desired depth and width in the epitaxial layer 110.

The depth and width of the trench 120, as well as the ratio of the width to the depth (the aspect ratio), can be controlled so that so a later-deposited insulating layer properly fills in the trench and minimizes the formation of voids. In some embodiments, the depth of the trench can range from about 0.1 to about 100 μm. In other embodiments, the depth of the trench can range from about 2 to about 5 μm. In yet other embodiments, the depth of the trench can be any suitable combination or sub-range of these amounts.

In some embodiments, the width of the trench can range from about 0.1 to about 50 μm. In other embodiments, the width of the trench can range from about 0.1 to about 1 μm. In yet other embodiments, the depth of the trench can be any suitable combination or sub-range of these amounts.

With such depths and widths in the trench, the aspect ratio of the trench can range from about 1:1 to about 1:50. In other embodiments, the aspect ratio of the trench can range from about 1:5 to about 1:8.3. In yet other embodiments, the aspect ratio of the trench can be any suitable combination or sub-range of these amounts.

In some embodiments, the structure of the trench 120 can be created using a dry etch process. The dry etchant used in dry etching processes, however, can sometimes leave damaged substrate materials in the bottom of the trench because the dry etching process using directional etching.

As well, the profile of the trench structure after the dry etching process can sometimes be unsatisfactory. For example, the trench profile can be unsatisfactory because it has not been optimized to round the bottom and control the taper angle to promote a complete fill of the trench with few or no seams or voids. This unsatisfactory trench profile can harm electrical performance of a conductive gate (of a MOSFET device) that will later be formed in the trench. For example, this electrical performance can suffer since the breakdown voltage, the gate to source leakage, and/or the switching speed can be reduced with such an unsatisfactory trench profile.

The damaged substrate material can be repaired and/or the unsatisfactory trench profile can be improved by using a soft etch process after the dry etch process. This supplemental soft etch process can be performed by etching the trench structure with a gas mixture containing CF₂ and O₂. The soft etch process can remove oxide on the trench sidewalls that may have been inadvertently oxidized during the dry etch process. But the soft etch process also unfortunately can remove some Si material in the trench, reducing the amount of silicon material that will be present in the channel region of the MOSFET structure (later be formed in the trench). This loss of Si material in the channel region can be detrimental for narrow pitch devices because it can limit the pitch that can be achieved with a given lithography apparatus due to undesirable trench widening once it is patterned and etched, resulting in the need to process at narrower pitches with more expensive lithography and stepper apparatus or increase the die size with an increased Rₛₚ (i.e., a higher die size or reduced die size with given RDS_{ON} at a higher process cost).

When dry etching processes use directional etching, they can also create sharp corners at the bottom of the trench, leading to leakage problems. To round these sharp corners, a high temperature process can be used to create a gate oxide in the bottom of the trench. This high temperature oxidation process can cause the Si material to flow during the oxide formation. As well, the high temperatures used can also cause up-diffusion of dopants from the epitaxial layer into the trench in an uncontrolled manner. To reduce or eliminate this up-diffusion, an expensive diffusion barrier (often made of As) is deposited in the trench, requiring additional processing and added costs. Thus, these additional process steps (the soft etch process and high temperature oxidation process) add both complexity and costs to the manufacturing process.

In some embodiments, these two additional processes (the soft etch process and high temperature oxidation process) can be eliminated by replacing them with a microwave (MW) radiation process to improve the profile of the trench and/or remove the damaged structure that results from the dry etch process. Where the substrate 105 comprises a Si or SiGe material, the MW radiation can be applied to the damaged or malformed trench. The MW radiation helps anneal out the defects that can be present in the trench profile by re-aligning the Si or SiGe atoms. As well, the MW radiation helps getter atoms or ions used in the etching gas (such as F, Cl, H, and/or H₂) that are left in the lattice structure by the dry etching process. This microwave heating process does not consume—or at least minimizes the consumption of—the Si material and avoids (or minimizes) the use of high temperature processing.

To improve the trench profile, the semiconductor structure can be radiated with microwaves, and optionally heated by a supplemental heating system to reach the desired temperature for the MW radiation. Any temperature can be used during the MW radiation that is sufficient to remove the damaged structure and/or improve the trench profile. In some embodiments, these low temperatures can be less than about 800° C. In other embodiments, these low temperatures can range from about 200 to about 800° C. In yet other embodiments, the temperatures can range from about 400 to about 550° C. In still other embodiments, these low temperatures can be any suitable combination or sub-range of these temperatures.

The microwave radiation can use any frequency or wavelength of microwaves that are allowed for industrial applications by government regulations. In some embodiments, the frequency and wavelength of the microwaves can be any of those allowed by international regulations for industrial applications. In other embodiments, the frequency of the microwaves can range from about 2.45 GHz to about 5.8 GHz and have a wavelength ranging from about 52 mm to about 123 mm.

The microwave radiation can be performed for any time sufficient to remove the damaged structure and/or improve the trench profile. In some embodiments, the time can range up to about 120 minutes, which is much shorter than the 5 to 6 hours that are often required in some conventional furnace processes. In other embodiments, this time can range from about 1 minute to about 120 minutes. In yet other embodiments, the time can range from about 2 minutes to about 60 minutes. In still other embodiments, the time can range from about 2 minutes to about 15 minutes. In even other embodiments, the time can be any suitable combination or sub-range of these amounts.

In some embodiments, a combination of rapid thermal processing (RTP) and a MW radiation can be used to remove the damaged structure and/or improve the trench profile. In these embodiments, the RTP can be performed from about 900° C. to about 1100° C. for about 2 to about 15 minutes and the MW anneal process can be performed from about 200° C. to about 550° C. for about 2 to about 30 minutes.

In some embodiments, the soft etch process and/or high temperature oxidation process can still be used to remove the damaged structure and/or improve the trench profile, but are followed by—instead of replaced with—the MW radiation. In these embodiments, the Si surface of the trench should be free of oxygen before corner rounding and damage healing with MW radiation. This configuration may be accomplished with a dry or wet pre-clean using ammonium biflouride or HF followed by a transfer to a MW processing chamber under a vacuum. The Si damage anneal and trench profile optimization with MW radiation may then be performed in a H₂ background gas to further react with residual oxide in the trench and provide H atoms that couple with the silicon damage in the trench. This process enables the Si atoms in the lattice to flow and the damage annealing to be performed at lower temperatures.

Thus, the soft etch process and/or high temperature oxidation process (the pre-clean process) can be coupled with a vacuum transfer into a microwave apparatus for subsequent Si damage removal and trench profile optimization using the MW radiation. A pre-clean process can therefore be performed on the structure illustrated in FIG. 2 in a first apparatus, and then the resulting structure transferred under vacuum to a second apparatus where the MW radiation can be applied to that structure to optimize the trench profile and/or remove the damaged material.

In other embodiments, though, a combined pre-clean and microwave anneal apparatus can be used. In these embodiments, the process (and apparatus used) could be configured so that both the pre-clean process and the MW radiation process can be performed in the same apparatus. In these configurations, this combined apparatus can be configured by using any first chamber modified from a pre-clean apparatus (such as those dry oxide etch apparatus made by Applied Materials or Tokyo Electron Labs) and coupling it with a second chamber modified from an apparatus capable of MW radiation using a load lock between the two chambers. Alternatively, this combined apparatus could be configured by using a cluster apparatus that places the wafers containing the substrates into a dry etch chamber. Once the dry etch is complete, the combined apparatus removes them from that chamber and then places them into the MW chamber, all while maintaining the wafers under a vacuum. Thus, the trench profile can be optimized and the damaged material removed without the need of having two apparatus and without the need for a transfer process between the apparatus.

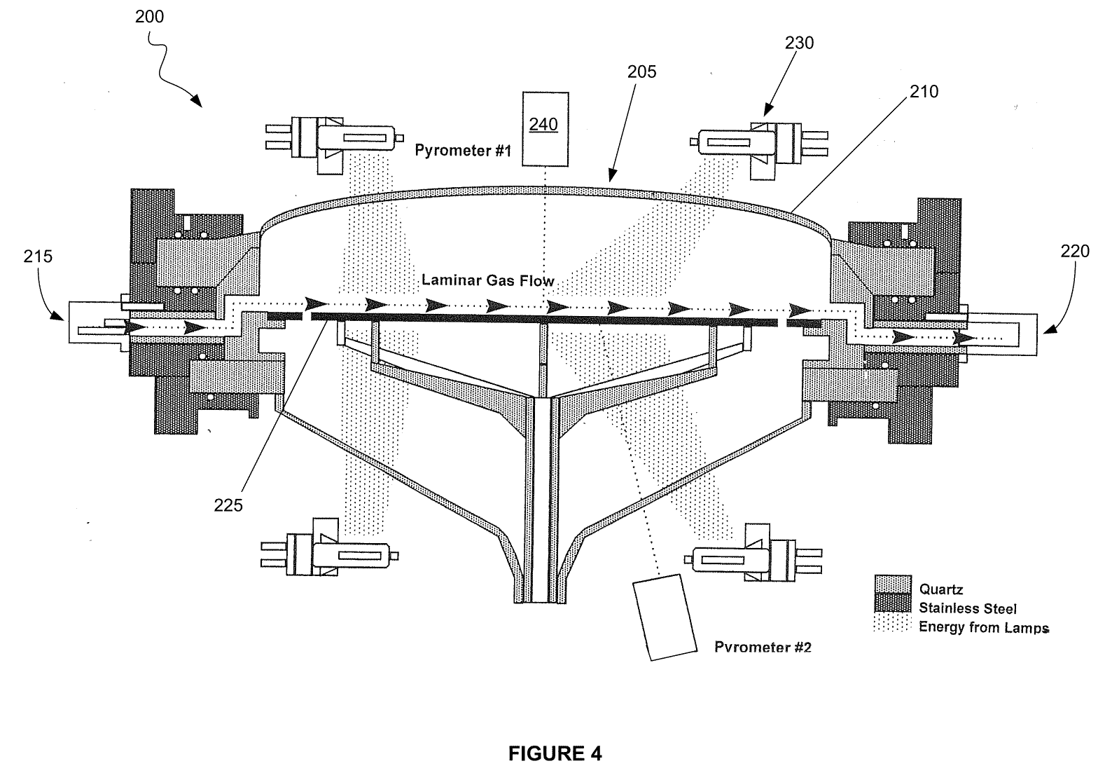

One example of a batch reactor that could be used for the microwave portion in such a combined apparatus is illustrated in FIG. 4. This batch reactor can obtain the desired trench profile and the damaged material can be removed while processing more than one wafer at a time. The batch reactor 200 contains a reactor chamber 205 that is formed by the reactor walls 210. The batch reactor 200 contains an inlet 215 and an outlet 220 for the gas mixture that will be used during the deposition process. The Si-containing gas(es), the carrier gas(es), and/or the dopant gas(es) can be introduced into the inlet 215 either as a single combination of gases or they can be introduced individually. The gas(es) exit via outlet 220 once the MW radiation is complete.

The reactor 200 also contains quartz susceptor plates 225. The plates 225 can be used with any number of wafers that is limited by the size of the reactor and the size of the area where the MW field is uniform. In some configurations, the number of wafers contained between the susceptor plates 225 can range from 1 to 12. In other configurations, the number of wafers contained between susceptor plates 225 can be one and multiple susceptor plates are used with one wafer between each set.

In some configurations, the quartz susceptor plates on either side of the wafer 225 can act as a microwave reflector and/or a highly doped Si-containing wafer can act as a microwave adsorber. These configurations allow the reactor 200 to focus the MW field into the susceptor plate and through the wafer above it. In other configurations, curved susceptor plates of convex or concave configurations (or combinations thereof) could be used to help make the microwave field uniform across the wafer independent of the applied microwave power.

In some configurations, composite susceptor plates could be used in the reactor 200. In these configurations, the susceptor plates contain adsorbing and reflecting layers in combination that could also be used in additional to the concave and or convex susceptor plates geometries to focus the microwave field at the wafer independent of the applied MW power. Examples of some composite susceptor plate structure include stacks of SOI (silicon-on-insulator) buried layers in Si which can be implanted at various depths with oxygen to generate the desired SiO₂ stacks within the Si wafer.

The reactor 200 also contains at least one MW source 230 that supplies the needed MW energy. In some configurations, the reactor can contain 4 to 20 MW sources. In the configurations illustrated in FIG. 4, the number of MW sources is four. The MW source(s) can be located around the reactor to provide MW energy to the desired locations in the chamber 205, as shown in FIG. 4.

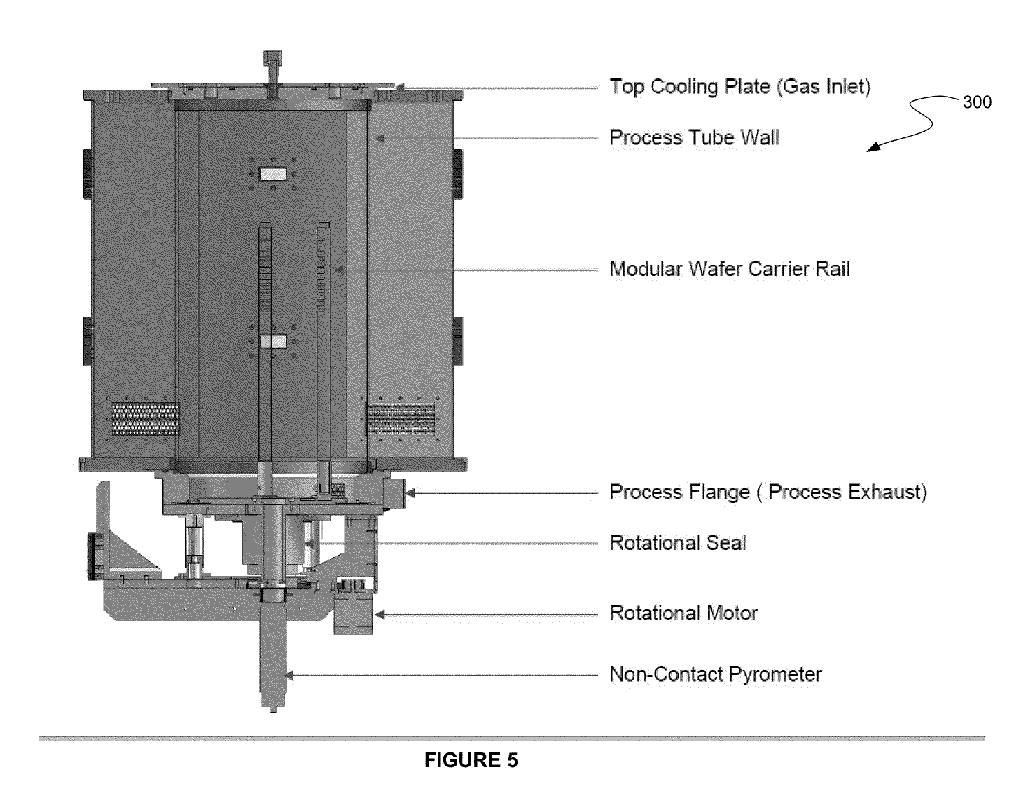

The reactor 200 can contain other components that are used in the deposition reactors in the semiconductor industry. For example, the reactor 200 can contain pyrometers 240 for measuring the temperature in the reaction chamber 205. As well, batch the reactor can contain pressure sensors, gas flow metering valves, hazardous gas monitors and the like. In other configurations, the batch reactor used for the MW processing using low temperatures could be a combination or hybrid of the batch reactor 200 shown in FIG. 4 and the batch reactor shown in FIG. 5.

The batch reactor 200 can be made of any material that is transparent to microwaves and yet can hold a vacuum. For example, as illustrated in FIG. 4, the reactor walls 210 can comprise quartz. When such a function is not needed, such as in the outer parts of the inlet 215 and the outlet 220, the material of the reactor 200 can be made from other materials, such as steel. In those embodiments where the reactor chamber 205 comprises quartz, it does not adsorb MW radiation and so it will be colder (i.e., about 50° C.) than the wafer temperature, making the batch reactor 200 cheaper to make and safer to operate.

In some embodiments, background gases may be used during the microwave radiation process to prevent (or reduce) oxygen or moisture from pining the grains. Examples of these gases include forming gas, i.e. H₂/N₂ or H₂, or combinations thereof. These gases can be present in any concentration sufficient to obtain this result, such as about 4% to about 100% of H₂ in N₂.

Once the trench profile has been optimized and/or the damaged structure removed, additional processing can be performed to complete the UMOS semiconductor device. In some devices, for example, this additional processing would include forming a gate insulating layer 125 in the bottom and sidewall of the trench 120. The gate insulating layer can be any dielectric material used in semiconductor devices. Examples of these dielectric materials include silicon oxide, silicon nitride, silicon oxynitride, hafnium oxide, (HfO2), and combinations thereof. In some embodiments, the gate insulating layer 125 can be made of a high quality silicon oxide material (or gate oxide).

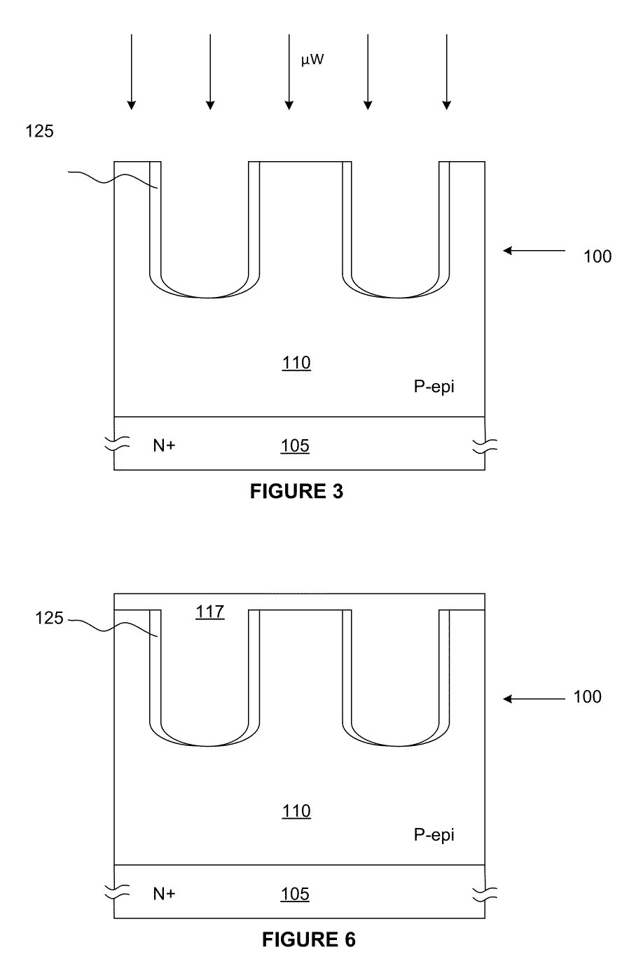

The gate insulating layer 125 can be formed by any process that creates a layer on the sidewall and bottom of the trenches 120. In some embodiments, the gate insulating layer 125 can be formed by depositing the desired dielectric material until it overflows the trenches 120. During this deposition, the thickness of the deposited dielectric material can be adjusted to any desired thickness. The dielectric material can be deposited using any known deposition process which can form a highly conformal step coverage within the trench. Examples of such deposition processes include chemical vapor deposition (CVD) processes, such as SACVD (sub-atmospheric CVD) or high density plasma oxide (HDP), or atomic layer deposition (ALD) processes. If needed, a reflow process can be used to reflow the deposited dielectric material, helping reduce voids or defects within the dielectric material. After the dielectric material has been deposited to the desired thickness, an etch back process can be used to remove the excess insulating material and form the gate insulating layer 125, as shown in FIG. 3.

In the embodiments where the gate insulating later 125 comprises a gate oxide layer, the gate oxide layer 125 can also be formed by oxidizing the epitaxial layer 110 in an oxide-containing atmosphere until the desired thickness of the oxide layer has been grown in the sidewall and bottom of the trench 120. In these embodiments, the oxidation process can be performed until the thickness of the gate oxide layer 125 can range from about 60 Å to about 500 Å.

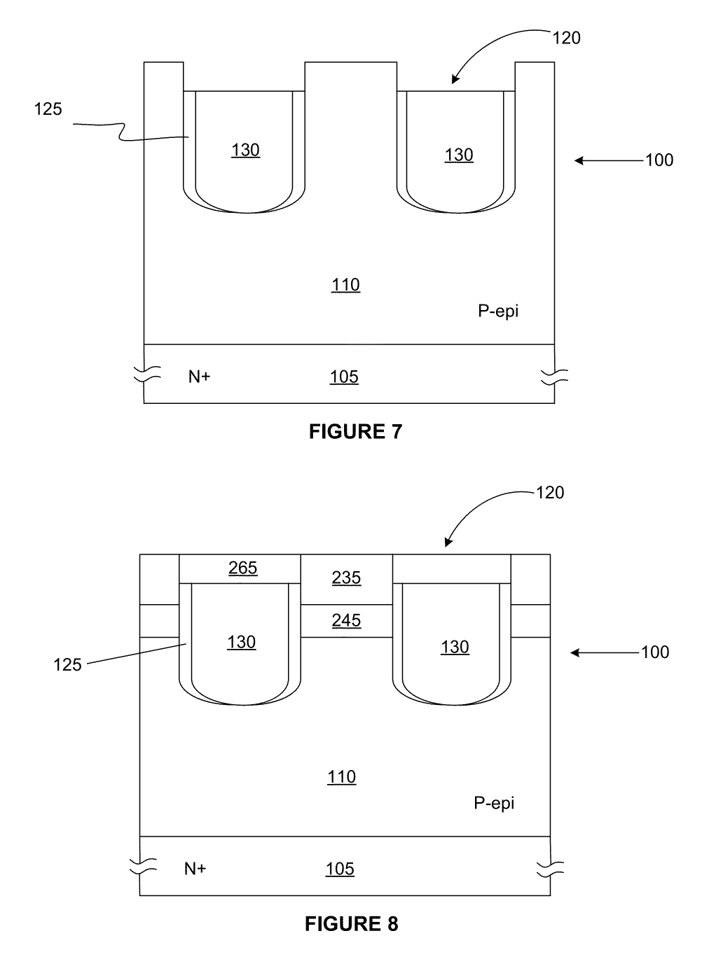

A gate conductor 130 (or gate 130) can be formed in the trench structure 120. In some embodiments, the gate conductor 130 can be formed by depositing the desired conductive material 117 (such as doped or undoped polysilicon) in and over the trench 120, as shown in FIG. 6. Then, an upper portion of the conductive layer 117 can be removed using any process, including an etchback process. The result of the removal process also removes the gate insulating layer 125 on the upper portion of the trench sidewall, leaving the gate 130 overlying the gate insulating layer 125 formed on the bottom of the trench 120 and sandwiched between the gate insulating layer 125 left on the lower potions of the trench sidewalls, as shown in FIG. 7.

The trench MOSFET structure can then be completed using any process known in the art. In some embodiments, a p-region 245 can be formed in an upper portion of the epitaxial layer 110, as shown in FIG. 7. The p-region can be formed using any process known in the art. In some embodiments, the p-regions regions 245 can be formed by implanting a p-type dopant in the upper surface of the epitaxial layer 110 and then driving-in the dopant using any known process.

Next, a contact region 235 can be formed on the exposed upper surface of the epitaxial layer 110. The contact region 235 can be formed using any process known in the art. In some embodiments, the contact regions 235 can be formed by implanting an n-type dopant in the upper surface of the epitaxial layer 110 and then driving-in the dopant using any known process. The resulting structures after forming the contact region 235 are illustrated in FIG. 8.

Then, the upper surface of the gate 130 is covered with an overlying insulating layer. The overlying insulating layer can be any insulating material known in the art. In some embodiments, the overlying insulating layer comprises any dielectric material containing B and/or P, including BPSG, PSG, or BSG materials. In some embodiments, the overlying insulating layer may be deposited using any CVD process until the desired thickness is obtained. Examples of the CVD processes include PECVD, APCVD, SACVD, LPCVD, HDPCVD, or combinations thereof. When BPSG, PSG, or BSG materials are used in the overlying insulating layer, they can be reflowed.

Then a portion of the overlying insulating layer is removed to leave an insulation cap 265. In the embodiments depicted in FIG. 8, the overlying insulating layer can be removed using any known mask and etching procedure that removes the material in locations other than the gate 130. Thus, an insulating cap 265 is formed over the gate 130. The excess amounts of the overlying insulating layer can be removed using any etch back or planarization process.

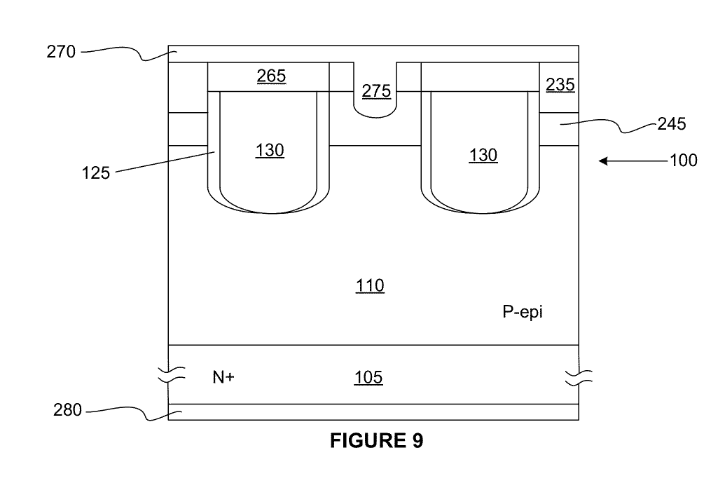

Next, as depicted in FIG. 9, the contact region 235 and the p-region 245 can be etched to form an insert region 275. The insert region 275 can be formed using any known masking and etching process until the desired depth (into the p-region 245) is reached. Next, as shown in FIG. 6, a source layer (or region) 270 can be deposited over the upper portions of the insulation cap 265 and the contact region 235. The source layer 270 can comprise any conductive and/or semiconductive material known in the art, including any metal, silicide, polysilicon, or combinations thereof. The source layer 270 can be deposited by any known deposition process, including chemical vapor deposition processes (CVD, PECVD, LPCVD) or sputtering processes using the desired metal as the sputtering target. The source layer 260 will also fill in the insert region 275.

After (or before) the source layer 270 has been formed, a drain 280 can be formed on the backside of the substrate 105 using any process known in the art. In some embodiments, the drain 280 can be formed on the backside by thinning the backside of the substrate 105 using any process known in the art, including a grinding, polishing, or etch processes. Then, a conductive layer can be deposited on the backside of the substrate 105 as known in the art until the desired thickness of the conductive layer of the drain is formed, as shown in FIG. 9.

In other embodiments, the MW radiation can be applied to the trench structure after it has been formed by wet etching processes. Wet etching processes sometimes leave material residues on the trench structure. These residues can be removed using the MW radiation processes described herein. In some configurations, the MW radiation can be performed with or without H₂ and/or N₂ background gases at temperatures ranging up to about 600° C.

The MW radiation of the damaged trench structures for UMOS semiconductor devices can provide several desirable features. First, the MW heating can repair the damaged trench structure and improve the trench profile, thereby enhancing the electric performance of the UMOS device. Second, since a supplemental soft etch process is not used on the trench, the MW heating does not consume any of the Si material in the channel region of the UMOS device. Third, the MW radiation can be performed at low temperatures, thereby avoiding or reducing Si slip and any unwanted dopant diffusion or autodoping that can accompany the use of high temperature processing. Fourth, the MW radiation at low temperatures avoids the need to use a diffusion barrier to control the dopant profile in the epitaxial layer.

There also exists safety improvements by using the processes described herein. Processing at temperatures less than about 600° C. with H₂ or H₂/N₂ mixtures provides the ability to dilute the H₂ gas. Another feature of low temperature processing below 600° C. is that Si nitridization reactions do not occur at these temperatures, allowing the use of a forming gas, (i.e., 3-5% H₂ in N₂). And using a combination of H₂ and MW radiation at temperatures lower than 550° C. also provides safety and cost advantages over some conventional processes that use H₂ at temperatures of 900° C.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

This application also relates to a trench formed in a semiconductor substrate by a process comprising: providing a semiconductor substrate; forming a trench in the substrate using a dry etching process; and radiating the trench using microwaves at a low temperature. This application also relates to a UMOS semiconductor device made by the process comprising: providing a semiconductor substrate; forming a trench in the substrate using a dry etching process; radiating the trench using microwaves at a low temperature; forming an insulating layer in the trench; forming a gate on the insulating layer; forming an insulating cap over the gate; and forming a source and a drain.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making a trench in a semiconductor substrate, comprising:
providing a semiconductor substrate;
forming a trench in the substrate using a wet or dry etching process; and
radiating the trench using microwaves at a low temperature.

2. The method of claim 1, wherein the radiation is performed at a temperature less than about 800° C.

3. The method of claim 1, wherein the radiation is performed at a temperature ranging from about 200 to about 800° C.

4. The method of claim 1, wherein the radiation is performed at a temperature ranging from about 400° C. to about 550° C.

5. The method of claim 1, wherein the radiation is performed for up to about 120 minutes.

6. The method of claim 1, wherein the radiation is performed for about 2 minutes to about 60 minutes.

7. The method of claim 1, wherein the semiconductor substrate comprises Si or SiGe.

8. The method of claim 7, wherein the microwave radiation re-aligns the Si or SiGe atoms in the substrate and anneal out the defects present after the dry etching process.

9. The method of claim 7, wherein the microwave radiation getters atoms or ions used in the dry etching process that are left in the lattice of the trench structure.

10. The method of claim 1, further comprising forming a gate of a MOSFET device in the trench.

11. A method for making a UMOS semiconductor device, comprising:
providing a semiconductor substrate;
forming a trench in the substrate using a wet or dry etching process;
radiating the trench using microwaves at a low temperature;
forming an insulating layer in the trench;
forming a gate on the insulating layer;
forming an insulating cap over the gate; and
forming a source and a drain.

12. The method of claim 11, wherein the radiation is performed at a temperature less than about 800° C.

13. The method of claim 11, wherein the radiation is performed at a temperature ranging from about 200 to about 800° C.

14. The method of claim 11, wherein the radiation is performed at a temperature ranging from about 400° C. to about 550° C.

15. The method of claim 11, wherein the radiation is performed for up to about 120 minutes.

16. The method of claim 11, wherein the radiation is performed for about 2 minutes to about 60 minutes.

17. The method of claim 11, wherein the semiconductor substrate comprises Si or SiGe.

18. The method of claim 17, wherein the microwave radiation re-aligns the Si or SiGe atoms in the substrate and anneal out the defects present after the dry etching process.

19. The method of claim 17, wherein the microwave radiation getters atoms or ions used in the dry etching process that are left in the lattice of the trench structure.

20. A method for making a trench in a semiconductor substrate, comprising:
providing a semiconductor substrate containing Si or SiGe;
forming a trench in the substrate using a wet or dry etching process; and
radiating the trench using microwaves at a temperature less than about 800° C.;
wherein the microwave radiation re-aligns the Si or SiGe atoms in the substrate and anneal out the defects present after the dry etching process and wherein the microwave radiation getters atoms or ions used in the dry etching process that are left in the lattice of the trench structure.
